(19) United States
(12) Patent Application Publication
(10) Pub. No.: US 2004/0161871 A1
(43) Pub. Date: Aug. 19, 2004

(54) Semiconductor device, method of manufacturing the same, circuit substrate and electronic equipment

(75) Inventor: Osamu Omori, Nagano-Ken (JP)

Correspondence Address: HOGAN & HARTSON L.L.P., 500 S. GRAND AVENUE, SUITE 1900, LOS ANGELES, CA, 90071-2611, US

(73) Assignee: SEIKO EPSON CORPORATION

(21) Appl. No.: 10/724,581

(22) Filed: Nov. 26, 2003

(30) Foreign Application Priority Data
Nov. 27, 2002 (JP) 2002-343815

(51) Int. Cl. H01L 21/00

(52) U.S. Cl. 438/68; 438/460

(57) ABSTRACT

A method of manufacturing a semiconductor device includes (a) connecting a first substrate with a second substrate disposed to be stacked on the first substrate and (b) cutting the first substrate and the second substrate in the same process with a cutting tool. The cutting tool includes a plurality of cutters disposed close to each other, having different cut widths and the first substrate and the second substrate are cut with the cutting tool so that the first substrate and the second substrate have different cut widths, in step (b).

### BACKGROUND OF THE INVENTION

1. Field of the Invention

The present invention relates to a semiconductor device, a method of manufacturing the same, a circuit substrate and electronic equipment.

2. Description of Related Art

It is known that an optical chip including an optical unit such as a light receiving part preferably has a space between the optical unit and a cover for sealing the optical unit. Therefore, a method is known for manufacturing an optical device in which an optical chip is cut into individual pieces, thereafter the optical unit is sealed by the cover so that a space is formed between the optical unit and the cover. When a substrate such as a wafer is cut by dicing and the like, substrate shavings resulting from dicing or other wastes are generated. Furthermore, when the waste is attached to the optical unit and sealed together without being removed, there is a problem that the waste can not be removed from the space after the optical unit has been sealed, so that the quality of the optical device decreases. Specifically, in a case of a solid-state imaging device having an optical unit provided with a microlens, since a microlens has a concavo-convex shape, the above waste is easy to adhere thereto and is difficult to be completely removed. Thus, in a case of a solid-state imaging device having an optical unit provided with a microlens, there is a problem that the quality thereof easily decreases.

The present invention is intended to enhance the reliability and the productivity of a product.

### SUMMARY OF THE INVENTION

A method of manufacturing a semiconductor device according to the present invention includes the steps of (a) connecting a first substrate with a second substrate disposed to be stacked on the first, and (b) cutting the first substrate and the second substrate in the same process with a cutting tool. Here, the cutting tool includes a plurality of cutters disposed close to each other, having different cut widths. In addition, the first substrate and the second substrate are cut with the cutting tool so as to have different cut widths of the first substrate and the second substrate in the step (b). According to the present invention, a plurality of the substrates which are stacked are cut in the same process so as to have different cut widths of the substrates. Therefore, there is no need for cutting the substrates in numbers, so that the productivity of the semiconductor device is enhanced.

In the method of manufacturing a semiconductor device, at least a part of the first substrate may have optical transparency. Furthermore, the second substrate may include a part which becomes an optical chip including an optical unit. Here, the part includes a plurality of parts.

In the method of manufacturing a semiconductor device, step (b) may also include the step of inserting the cutting tool into the first substrate and the second substrate from a side of the first substrate.

In the method of manufacturing a semiconductor device, the cutting tool may include a first cutter cutting the first substrate and a second cutter cutting the second substrate. In addition, a cut width of the first substrate by the first cutter may be larger than a cut width of the second substrate by the second cutter, in step (b).

In the method of manufacturing a semiconductor device, the length of the first cutter may be larger than the thickness of a part which is cut, of the first substrate.

In the method of manufacturing a semiconductor device, the length of the second cutter may be larger than the thickness of a part which is cut, of the second substrate.

In the method of manufacturing a semiconductor device, step (b) may also include the step of positioning the first cutter with an interval from a surface of the second substrate at the time of cutting the second substrate. This can avoid cutting the second substrate with the first cutter.

In the method of manufacturing a semiconductor device, an electrode may be formed on the part which becomes an optical chip on the second substrate, and outside the optical unit. In addition, a part of the first substrate located above the electrode may be removed with the first cutter in step (b). This enables a space above the electrode of the second substrate to be opened, so that a connection to the electrode is easily established.

The method of manufacturing a semiconductor device may also include the steps of attaching a sheet to the second substrate before step (b), and cutting the second substrate not so as to penetrate the sheet with the cutting tool in step (b). This enables the second substrate which was cut to be retained on the sheet, and thereby the following processes are facilitated.

The method of manufacturing a semiconductor device may also include the steps of forming a trench along a cut line of the first substrate before step (b), and cutting the first substrate along the cut line in step (b). This enables the cut line to be made thinner than other parts of the substrate, so that the first substrate can be easily cut with the first cutter. In addition, forming the trench clearly specifies a cut position of the first substrate.

In the method of manufacturing a semiconductor device, step (b) may also include the step of cutting and separating the first substrate and the second substrate into individual pieces that include a part of the first substrate and a part of the second substrate which are placed face to face and fixed to each other.

In the method of manufacturing a semiconductor device, step (a) may also include the steps of placing the first substrate and the second face to face through a spacer, and fixing the first substrate to the second substrate through the spacer.

In the method of manufacturing a semiconductor device, step (a) may also include the steps of bonding the first substrate with the second substrate through an optically transparent adhesive, and fixing the first substrate to the second substrate through the optically transparent adhesive.

The method of manufacturing a semiconductor device may also include the steps of forming a connecting part which connects a plurality of covers to each other in the first substrate, fixing a plurality of the covers to the second substrate in step (a), and cutting the connecting part in the (b).

A semiconductor device according to the present invention is manufactured by the method described above. Also, a semiconductor device according to the present invention includes the semiconductor device described above and a supporting member which supports the semiconductor device. Further, onto a circuit substrate according to the present invention, the semiconductor device described above is mounted. Moreover, electronic equipment according to the present invention includes the semiconductor device described above.

### BRIEF DESCRIPTION OF DRAWINGS

FIGS. 1(A) through 1(C) are diagrams illustrating a method of manufacturing a semiconductor device according to a first embodiment of the present invention.

FIG. 2 is a diagram illustrating the method of manufacturing a semiconductor device according to the first embodiment of the present invention.

FIG. 3 is a diagram illustrating the method of manufacturing a semiconductor device according to the first embodiment of the present invention.

FIGS. 4(A) and 4(B) are diagrams illustrating the method of manufacturing a semiconductor device according to the first embodiment of the present invention.

FIGS. 5(A) and 5(B) are diagrams illustrating the method of manufacturing a semiconductor device according to the first embodiment of the present invention.

FIGS. 6(A) and 6(B) are diagrams illustrating a semiconductor device according to the first embodiment of the present invention.

FIGS. 7(A) and 7(B) are diagrams illustrating a method of manufacturing a semiconductor device according to a modification of the first embodiment of the present invention.

FIGS. 8(A) through 8(E) are diagrams illustrating a method of manufacturing a semiconductor device according to another modification of the first embodiment of the present invention.

FIGS. 9(A) through 9(C) are diagrams illustrating a method of manufacturing a semiconductor device according to a second embodiment of the present invention.

FIGS. 10(A) and 10(B) are diagrams illustrating a method of manufacturing a semiconductor device according to a third embodiment of the present invention.

FIG. 11 is a diagram illustrating the method of manufacturing a semiconductor device according to the third embodiment of the present invention.

FIG. 12 is a diagram illustrating a semiconductor device and a circuit substrate according to an embodiment of the present invention.

FIG. 13 is a diagram illustrating a semiconductor device according to an embodiment of the present invention.

FIG. 14 is a diagram illustrating a semiconductor device according to an embodiment of the present invention.

FIG. 15 is a diagram showing electronic equipment according to an embodiment of the present invention.

FIG. 16 is a diagram showing electronic equipment according to an embodiment of the present invention.

FIGS. 17(A) and 17(B) are diagrams showing electronic equipment according to an embodiment of the present invention.

### DETAILED DESCRIPTION OF THE PREFERRED EMBODIMENTS

An embodiment of the present invention will be described hereinafter referring to the accompanying drawings.

(First Embodiment)

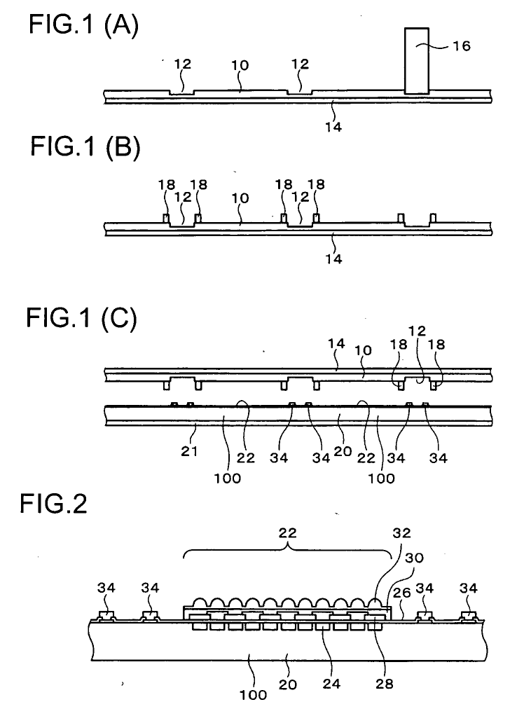

FIGS. 1(A) through 6(B) are diagrams illustrating a semiconductor device and a method of manufacturing the same according to a first embodiment of the present invention. In the present embodiment, an optical device and a method of manufacturing the same will be described as an example. In the present embodiment, a first substrate 10 and a second substrate 20 are used.

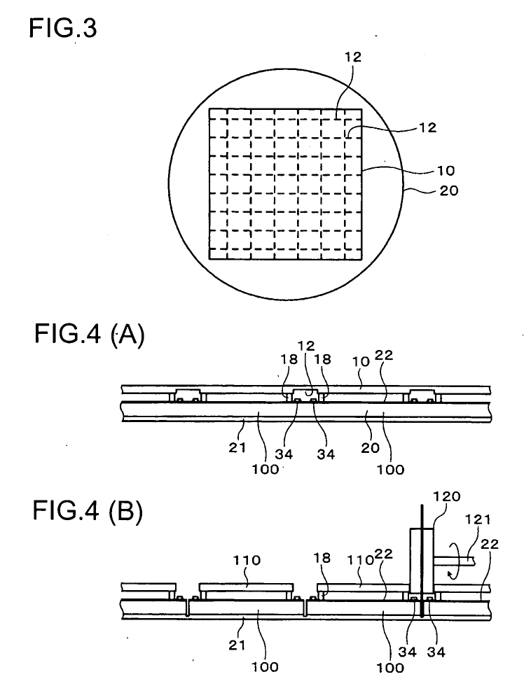

As shown in FIG. 1(A), the first substrate 10 is prepared. Although the size and the shape of the first substrate 10 are not specifically limited, the size is preferably the same as that of the second substrate 20, and the shape is more preferably the same as that of the second substrate 20. Furthermore, the substrate 10 may be, for example, a quadrangle as shown in FIG. 3. At least a part of the first substrate 10 has optical transparency. Optical glass can be used as the first substrate 10. If only the first substrate 10 is optically transparent, the magnitude of the optical loss thereof is of no object. In addition, the first substrate 10 may transmit only light having a specific wavelength. For example, the first substrate 10 may not transmit light in the infrared range but transmit visible light. The optical loss of the first substrate 10 may be small for visible light and may be large for light in the infrared range. Furthermore, optically functional films such as an antireflective coat and an infrared blocking film may be formed on a surface of the first substrate 10. This saves the need for installing a member having an optical function in addition to a substrate, so that an optical device and the like can be further reduced in size.

A trench 12 may be formed on the first substrate 10 as shown in FIG. 1(A). When the trench 12 is formed by cutting the first substrate 10, attaching a supporting member such as a sheet 14 to the substrate 10 improves the efficiency of the job for the process so as to avoid cracks in the first substrate 10. The trench 12 may be formed by half-cutting the first substrate 10. The half-cutting technique is not cutting the first substrate 10 completely, but forming the trench 12 by cutting the first substrate 10 along a thickness direction thereof as shown in FIG. 1(A). In this case, the trench 12 may be formed by cutting from a surface of the first substrate 10 with a dicing blade 16. The trench 12 is formed on a cut line (a virtual line for cutting) of the first substrate 10. Namely, in a cutting process described later, the first substrate is cut along the cut line. For example, as shown in FIG. 3, the trench 12 here including a plurality of trenches may be laid out in a lattice structure. Forming the trench 12 makes the thickness of the first substrate 10 at the cut line be thinner than other parts of the first substrate 10, and thereby the first substrate 10 can be easily cut with a cutting tool 120 (specifically, a first cutter 122) described later. In addition, forming the trench 12 enables a cut position of the first substrate 10 to be clearly specified. As a modification, the first substrate 10 may not include the trench 12.

Next, in the present embodiment, the first and the second substrates 10 and 20 are attached to each other through at least a single spacer 18. The spacer 18 which is provided may include a plurality of spacers. For example, the spacer 18 is formed on one of the first and the second substrates 10 and 20. Then, one of the first and the second substrates 10 and 20 is attached to the other of the first and the second substrates 10 and 20 through spacer 18. As an example, the spacer 18 of a lattice structure is provided on the first substrate 10 as shown in FIG. 1(B). The spacer 18 is provided on each part which is cut to become a transparent substrate 110, of the first substrate 10. In the example shown in FIG. 1(B), spacers 18 are each provided to surround the trench 12 (see, FIG. 3). The spacer 18 may be formed continuously (without a break) with an adjacent spacer. In this case, attaching of the spacer 18 is facilitated. The spacer 18 has a form surrounding an optical unit 22 described later.

In the present embodiment, the spacer 18 is formed by a resin. In view of adhesion to the first and the second substrates 10 and 20, the resin having adhesiveness, such as thermoplastic resin, light curable resin, heat curable resin, a combination of these resin may be used. For example, the spacer 18 may be formed by forming a layer of photosensitive resin (a photo resist such as photosensitive polyimide) on the first substrate 10, thereafter applying photolithography thereto for patterning the layer. Otherwise, the spacer 18 may be formed by screen printing. Here, temporarily curing the spacer 18 formed by a light curable resin or a heat curable resin can avoid transforming thereof. In addition, when the resin forming the spacer 18 is ultraviolet rays (UV) curable, weak irradiation of UV is available for temporarily curing. Here, temporarily cured means a condition where the resin has not been completely cured, and where the fluidity of the temporarily cured resin is lower than that of the resin under room temperature. This prevents the resin from transforming when the first and the second substrates 10 and 20 are attached to each other through the spacer 18, and thereby the resin can be prevented from attaching to the optical unit 22 described later. Therefore, the disadvantage of inputting and outputting of light to and from the optical unit due to adhesion of the resin can be avoided. Furthermore, at least a surface of the spacer 18 is preferably composed of an insulating material.

As shown in FIG. 1(C), the second substrate 20 is prepared. A sheet 21 may be attached to the second substrate 20 in order to improve the efficiency of the processing job in the cutting process described later. FIG. 2 is a diagram showing a magnification of a part of the second substrate 20. The second substrate 20 has an optical chip 100 here including a plurality of optical chips which includes the optical unit 22. The optical chip 100 includes the optical unit 22 and electrodes 34. The optical unit 22 includes a part (a light receiving part or a light emitting part) which light enters or is emitted from, and a part for converting optical energy into other energy (for example, electrical energy) or for converting other energy (for example, electrical energy) into optical energy. One of the optical units 22 may include an energy converting part (a light receiving part or a light emitting part) 24 including a plurality of energy converting parts.

In the present embodiment, as an example, a solid-state imaging device (for example, a CCD, specifically a CCD provided with a photo diode, and an image sensor such as a CMOS sensor) will be described. In this case, each optical unit 22 includes the energy converting part (a light receiving part, an image sensing part, or the like) 24 including a plurality of energy converting parts. As shown in FIG. 2, the energy converting part 24 includes a plurality of energy converting parts two-dimensionally arranged so as to sensor an image. The energy converting part 24 may be covered by a passivation film 26 which has optical transparency. When the second substrate 20 includes a semiconductor substrate (for example, a semiconductor wafer), the passivation film 26 may be formed by a silicon oxide film or a silicon nitride film.

The optical unit 22 may include a color filter 28. The color filter 28 may be formed on the passivation film 26. In addition, a planerizing layer 30 may be installed on the color filter 28. A microlens array 32 may be formed on a surface of the optical unit 22. In this case, the first substrate 10 and the spacer 18 seal at least an area where the microlens array 32 is formed, among areas on the second substrate 20.

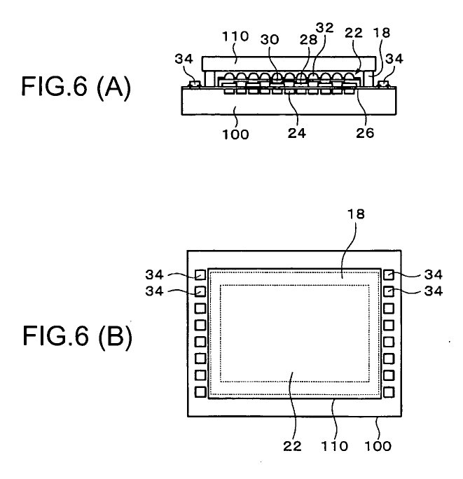

A plurality of the electrodes 34 are formed on the second substrate 20. Although the electrodes 34 shown in FIG. 2 include a bump formed on a pad, it may include only the pad. As shown in FIG. 2, the electrodes 34 are preferably formed outside the optical unit 22, on a part which becomes the optical chip 100. For example, the electrodes 34 may be formed between two of adjacent optical units (which are referred to as the optical unit 22). One group of the electrodes 34 (including a plurality of electrodes) correspond to a single optical unit 22. For example, as shown in FIG. 6(B), the electrodes 34 may be disposed along a plurality of sides of the optical unit 22 (for example, on two opposed sides). Furthermore, the electrodes 34 may be disposed along a single side of the optical unit 22.

A mark for recognizing a cut line (not shown in the drawing) is preferably formed on the second substrate 20. When the first substrate 10 is optically transparent, the mark on the second substrate 20 may be recognized through the first substrate 10.

As shown in FIG. 1(C), the first and the second substrates 10 and 20 are placed face to face. Specifically, a plane where the optical unit 22 is formed, of the second substrate 20 and the first substrate 10 are placed face to face. FIG. 3 is a plan view showing the first and the second substrates 10 and 20 which are placed face to face. When the first substrate 10 includes the trench 12, a plane having the trench 12 may be opposed to the second substrate 20. In addition, when a supporting member such as the sheet 14 is provided on the first substrate 10, an opposite side of the plane where the supporting member is provided may be opposed to the second substrate 20. In this case, the spacer 18 intervenes between the first and the second substrates 10 and 20. The spacer 18 is disposed to surround the optical unit 22 of the second substrate 20 (see, FIG. 6(B)).

As shown in FIG. 4(A), the first and the second substrates 10 and 20 are attached to each other through the spacer 18. For example, when the spacer 18 is formed by a heat curable resin, the spacer 18 provided on the first substrate 10 is in contact with the second substrate 20, thereafter the spacer 18 is heated so as to develop adhesion thereof. In addition, for example, when the first substrate 10 is optically transparent, the spacer 18 may be formed by a light curable resin. Then, the spacer 18 may be bonded to the second substrate 20 by irradiating the spacer 18 with light from a side of the first substrate 10. Otherwise, an adhesive may be provided between the second substrate 20 and the spacer 18. In this case, when the first substrate 10 is optically transparent, and the adhesive is a light curable resin, the spacer 18 may be bonded to the second substrate 20 by irradiating the adhesive with light from a side of the first substrate 10. Thus, the optical unit 22 is sealed by the first substrate 10 and the spacer 18. In the present embodiment, the optical unit 22 is sealed so that a space is formed between the first and the second substrates 10 and 20. Here, the space may be evacuated to the extent that the pressure thereof becomes lower than atmosphere pressure, or that the space becomes a vacuum. Otherwise, the space may be filled with nitrogen, dry air, and the like. For example, the above structure is obtained by performing a sealing process under the pressure lower than atmosphere pressure or a vacuum, or under an atmosphere of nitrogen, dry air, or the like. This enables water vapors and the like in the space to be reduced. Therefore, dew condensation in products such as a semiconductor device and an electrical part, and bursting of a product due to an increase of the pressure of the space in a heating process, can be avoided. Here, the sheet 14 attached to the first substrate 10 is peeled off, if necessary. Furthermore, the first and the second substrates 10 and 20 are preferably cleaned and dried right before the sealing process. The reason is that cleaning the optical unit 22 right before sealing enables dust and the like in the space to be avoided, so that a yield of a final product can be further improved.

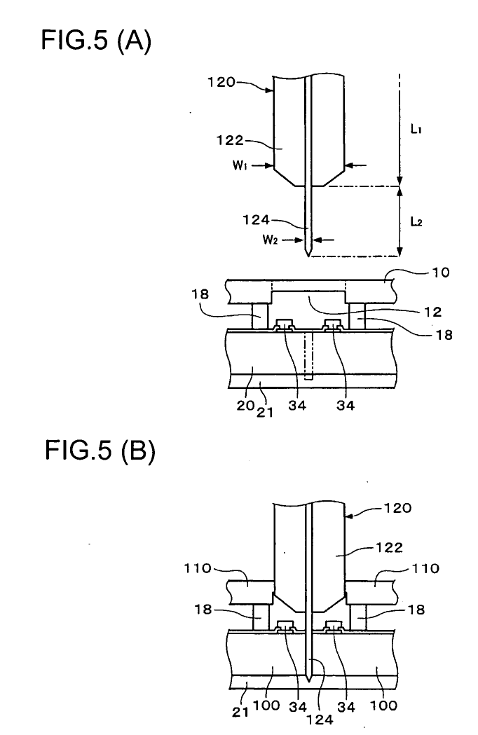

Next, a cutting process of the first and the second substrates 10 and 20 will be described. Here, FIG. 5(A) and FIG. 5(B) are magnified diagrams of the first and the second substrates for explaining this process.

In this process, as shown in FIG. 4(B), the first and the second substrates 10 and 20 are cut in a lump (simultaneously). The cutting is performed avoiding a part which becomes the transparent substrate 110, of the first substrate 10. Namely, the first substrate 10 is cut outside an area surrounded by the spacer 18 (where the optical unit 22 is located) and the spacer 18, or is cut so that at least a part of the spacer 18 remains. The first substrate 10 may be cut along the trench 12.

This process is performed using the cutting tool 120. The cutting tool 120 may be a blade used for dicing of a semiconductor wafer. For example, the cutting tool 120 is formed into a disk shape. A shaft part 121 connected to the center of the disk rotates, and thereby the first and the second substrates 10 and 20 are cut with a blade (for example, an abrasive grain) formed on a periphery part of the cutting tool 120.

As shown in FIG. 5(A), the cutting tool 120 includes a plurality of cutters (in FIG. 5(A), a first cutter 122 and a second cutter 124). Each cutter cuts any substrate of a plurality of the substrates which are stacked. Specifically, the first cutter 122 cuts the first substrate 10, while the second cutter 124 cuts the second substrate 20. A plurality of the cutters (the first and the second cutters 122 and 124) are disposed on the same cut line, and thereby a plurality of the substrates (the first and the second substrates 10 and 20) are cut in the same process (for example, in a lump) as the cutting tool 120 moves. Here, the first and the second cutters 122 and 124 are a part of the cutting tool 120. The cutters may be integrally formed from one member, or may be formed by combining individual members.

In this process, any substrate of a plurality of the substrates is cut so that a cut width thereof is different from that of another substrate. Specifically, the first and the second substrates 10 and 20 are cut so as to have different cut widths. For example, the first and the second cutters 122 and 124 are formed into a disk shape and have a blade (for example, an abrasive grain) on a periphery part thereof, and then the width of each periphery part (the thickness of the blade) is different from each other. Namely, a plurality of step parts are formed by the first and the second cutters 122 and 124, on the periphery part of the cutting tool 120.

As shown by a chain double-dashed line of FIG. 5(A), a cut width of the first substrate 10 may be larger than that of the second substrate 20. Namely, as shown in FIG. 5(A), the width W1 of the first cutter 122 (the thickness of the blade) may be larger than the width W2 of the second cutter 124 (the thickness of the blade).

In addition, the width W1 of the first cutter 122 is practically the same as the width of the trench 12. Here, being practically the same includes cases where the widths are completely the same, and where the widths are the same in consideration of a margin of error. Otherwise, the width W1 of the first cutter 122 may be smaller than the width of the trench 12. In this case, the first substrate 10 is cut inside the trench 12, so that the transparent substrate 110 includes a step on an edge part. Otherwise, the width W1 of the first cutter 122 may be larger than the width of the trench 12. Furthermore, the width W1 of the first cutter 122 may be larger than an interval between two adjacent spacers (which are referred to as the spacer 18). In this case, a part of the spacer 18 is cut when the first substrate 10 is cut.

The second cutter 124 cuts the second substrate 20 outside the optical unit 22, and further outside the electrodes 34. Between two of the adjacent optical units (which are referred to as the optical unit 22), the electrodes 34 which correspond to the optical unit 22 are formed. The second substrate 20 is cut between two of the electrodes 34 (including a plurality of electrodes). Here, as shown in FIG. 5(A), the periphery part of the first and the second cutters 122 and 124 may be in a sharp shape.

The length L1 of the first cutter 122 (the length of a part which is outside the shaft part 121 of the cutting tool 120, of the first cutter 122) is larger than at least the thickness of the first substrate 10 at the cut line (for example, the thickness of a trench part). In addition, the length L2 of the second cutter 124 (the length of a part which is outside the first cutter 122, of the second cutter 124) is larger than at least the thickness of the second substrate 20.

As shown in FIG. 5(B), the first and the second cutters 122 and 124 may be inserted into the first and the second substrates 10 and 20 from a side of the first substrate 10. The cutting tool 120 moves along and parallel to the cut line (for example, the trench 12) as shown in FIG. 5(B). The edge part (the periphery part) of the first cutter 122 is positioned above the second substrate 20 with an interval. In the example shown in FIG. 5(B), since a plane where the trench 12 is formed, of the first substrate 10 faces the second substrate 20, a surface of the first substrate 10 keeps away from the second substrate 20, so that the first cutter 122 hardly contacts the second substrate 20. This can prevent the first cutter 122 from cutting the second substrate 20.

In the example shown in FIG. 5(B), the first and the second substrates 10 and 20 are cut (full-cut) into an individual piece in order to obtain the optical chip 100 including a single optical unit 22 which is sealed. As a modification, for example, the second substrate 20 may not be completely cut into an individual piece but may be cut (for example, half-cut) to the extent that a trench is formed on a surface thereof. In this case, in the following process, the second substrate 20 may be isolated into an individual piece along the trench formed on the surface by polishing the second substrate 20 from a back side so as to obtain the optical chip 100.

A part which is above the electrodes 34, of the first substrate 10 may be removed with the first cutter 122. This can open a space above the electrodes 34 disposed between two adjacent transparent substrates (which are referred to as the transparent substrate 110), when the first substrate 10 is cut into the transparent substrate 110 here including a plurality of transparent substrates which is an individual piece. Therefore, since a space above the electrodes 34 of the second substrate 20 is opened, an electrical connection to the electrodes 34 is easily established.

When the sheet 21 is attached to the second substrate 20, the second substrate 20 is preferably cut (full-cut, in FIG. 5(B)) so that the sheet 21 is not penetrated. This enables the second substrate 20 which was cut to be retained on the sheet 21, so that the following processes are facilitated. Specifically, in a case of the first and the second substrates 10 and 20 being cut into individual pieces, a plurality of the individual pieces can be held in a lump, so that following processes are greatly facilitated.

According to the method of manufacturing a semiconductor device according to the present embodiment, the first and the second substrates 10 and 20 which are stacked are cut in a lump so as to have different cut widths. Therefore, there is no need for cutting the substrates in numbers, so that the productivity of the semiconductor device can be enhanced. Furthermore, since the first and the second substrates 10 and 20 are cut after the optical unit 22 is sealed, dust is not mixed in the sealed part, so that the reliability of a semiconductor device can be enhanced.

FIG. 6(A) and FIG. 6(B) are diagrams explaining the semiconductor device according to the present embodiment. In the present embodiment, an optical device will be described as an example. The optical device includes the transparent substrate 110, the optical chip 100, and the spacer 18. Light enters the optical unit 22 from the transparent substrate 110. The optical unit 22 formed on the optical chip 100 is sealed by the transparent substrate 110 and the spacer 18. A space is formed between the optical unit 22 and the transparent substrate 110. The space may be a vacuum, or may be filled with nitrogen and dry air. This avoids dew condensation in the optical unit 22. The electrodes 34 are provided on the optical chip 100, outside the optical unit 22, and further outside a member sealing the optical unit 22 (the transparent substrate 110 and the spacer 18). Other details are the same as the details explained in the previous embodiment of the method of manufacturing a semiconductor device.

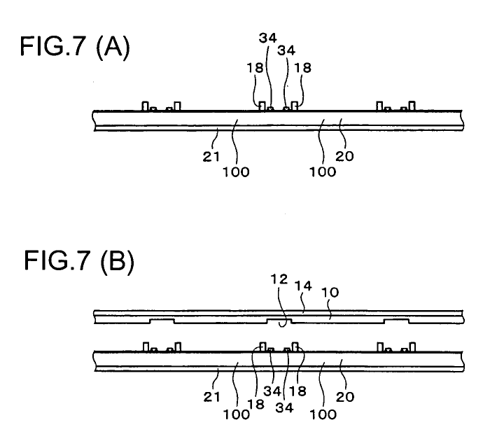

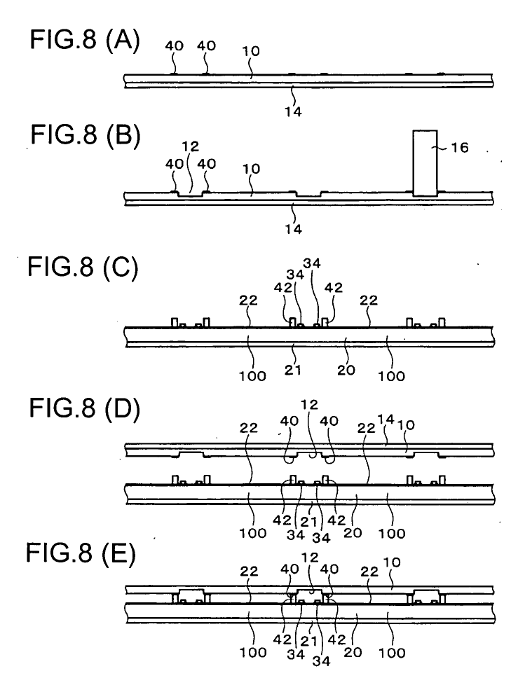

FIG. 7(A) through FIG. 8(E) are diagrams showing a modification of the present embodiment. In the following explanation, contents (a structure, an action, a function, and an effect) which are the same as those of other embodiments and are assumable will be omitted. Here, the present invention includes contents achieved by combining a plurality of embodiments.

FIG. 7(A) and FIG. 7(B) are diagrams illustrating a method of manufacturing a semiconductor device according to a modification of the present embodiment. In this modification, as shown in FIG. 7(A), the spacer 18 is formed on the second substrate 20. When a passivation film is formed on the second substrate 20, the spacer 18 may be formed thereon. Otherwise, the passivation film may not be formed on an area where the spacer 18 is formed. Then, as shown in FIG. 7(B), the first substrate 10 is attached to the spacer 18. The details described about connecting the second substrate 20 to the spacer 18 can be applied to connecting the first substrate 10 to the spacer 18.

FIG. 8(A) through FIG. 8(E) are diagrams illustrating a method of manufacturing a semiconductor device according to another modification of the present embodiment. Although the first and the second substrates 10 and 20 are also used in this modification, the spacer is formed by a metal. Namely, the spacer is formed by a metal on one of the first and the second substrates 10 and 20, and then the other of the first and the second substrates 10 and 20 is attached to the spacer.

As shown in FIG. 8(A), a brazing material (or a seal metal) 40 is provided on the first substrate 10. The brazing material 40 may be either of a soft-soldering material and a hard-soldering material. A method of providing the brazing material 40 may be any of vapor deposition, sputtering, CVD, and plating (for example, electroless plating). If the brazing material 40 is a paste material as a soldering paste, screen printing may be applied. The brazing material 40 is provided on a position where the spacer is attached.

As shown in FIG. 8(B), the trench 12 is formed on the first substrate 10. Although the trench 12 is formed after the brazing material 40 is provided in this modification, the order may be reversed.

As shown in FIG. 8(C), a spacer 42 is formed on the second substrate 20. The spacer 42 is formed by metals such as nickel and gold. Plating (for example, electroless plating) can be applied as a forming method of the spacer 42.

As shown in FIG. 8(D), the first and the second substrates 10 and 20 are attached to each other through the spacer 42. Specifically, the first substrate 10 is bonded to the spacer 42. Brazing is applied to the bonding. Specifically, the brazing material 40 formed on the first substrate 10 is melted by heating so as to bond the first substrate 10 to the spacer 42.

After the first and the second substrates 10 and 20 are attached to each other as shown in FIG. 8(E), the process shown in FIG. 4(C) is performed. In the optical device according to the above methods, the optical unit 22 is sealed by the transparent substrate 110, the spacer 42, and the brazing material 40. Here, a metal spacer may be provided on the first substrate 10, and then the spacer may be bonded to the second substrate 20. In addition, an adhesive may be used instead of the brazing material.

(Second Embodiment)

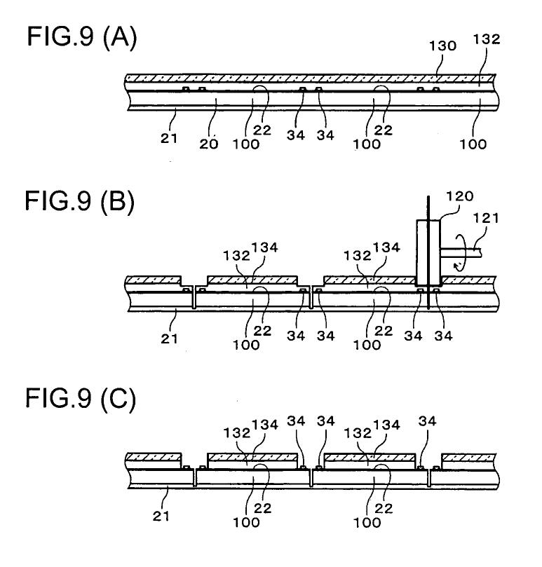

FIG. 9(A) through FIG. 9(C) are diagrams illustrating a method of manufacturing a semiconductor device according to a second embodiment of the present invention. In the present embodiment, a method of manufacturing an optical device will be described as an example, too. In the present embodiment, a first substrate 130 and the second substrate 20 are attached to each other through an adhesive layer 132. The details of the first substrate 10 which have been explained in the previous embodiment can be applied to the first substrate 130.

As shown in FIG. 9(A), the first and the second substrates 10 and 20 are attached to each other through the adhesive layer 132. The adhesive layer 132 has optical transparency. Specifically, the optical transparency of the adhesive layer 132 may be as high as that of air. A thermoplastic resin may be used as the adhesive layer 132. For example, a photosensitive resin (a photo resist and the like) which is thermoplastic may be used. Here, the adhesive layer 132 may be temporarily cured for easy handling. Then, adhesion thereof may be developed after the adhesive layer 132 contacts either the first and the second substrates 130 and 20. For example, when the adhesive layer 132 is a UV curable thermoplastic resin, irradiating of UV can be applied to temporarily curing. In a case of the adhesive layer 132 being formed on a microlens array 32, each absolute refractive index of both is different from each other. Specifically, when the microlens array 32 includes a convex lens, the absolute refractive index of the adhesive layer 132 is preferably smaller than that of the microlens array 32. On the contrary, when the microlens array 32 includes a concave lens, the absolute refractive index of the adhesive layer 132 is preferably larger than that of the microlens array 32.

The adhesive layer 132 may be continuously formed on the second substrate 20 to cover a part which becomes the optical chip 100 here including a plurality of parts. Namely, the adhesive layer 132 may be formed to cover the optical unit 22 here including a plurality of optical units and an area between two adjacent optical units (which are referred to as the optical unit 22). The optical unit 22 is sealed by the adhesive layer 132. As a modification, the adhesive layer 132 may be formed on the optical unit 22, while avoiding the area between two adjacent optical units (which are referred to as the optical unit 22).

As shown in FIG. 9(B), the first and the second substrates 130 and 20 are cut in a lump (simultaneously). Although a trench is not formed on the first substrate 130 in the present embodiment, a trench may be formed as the first embodiment. The first and the second substrates 130 and 20 are cut using the cutting tool 120. In the example shown in FIG. 9(B), the first substrate 130 is cut so as to form the transparent substrate 134 here including a plurality of transparent substrates. The second substrate 20 is cut so as to form the optical chip 100 here including a plurality of optical chips. The optical unit 22 of the optical chip 100 is sealed by the transparent substrate 134 and the adhesive layer 132. Here, the details of the cutting process are the same as the details explained in the first embodiment.

As shown in FIG. 9(C), when a part of the adhesive layer 132 remains between two of the adjacent transparent substrates (which are referred to as the transparent substrates 134) (for example, on the electrodes 34), a removing process thereof is performed. For example, etching with a solvent and sputtering, or ashing with plasma (02 plasma and the like) can remove a part of the adhesive layer 132, utilizing the transparent substrate 134 as a mask.

The present embodiment can also achieve the effects which have been previously explained in other embodiments. Other details are the same as the details explained in the first embodiment.

(Third Embodiment)

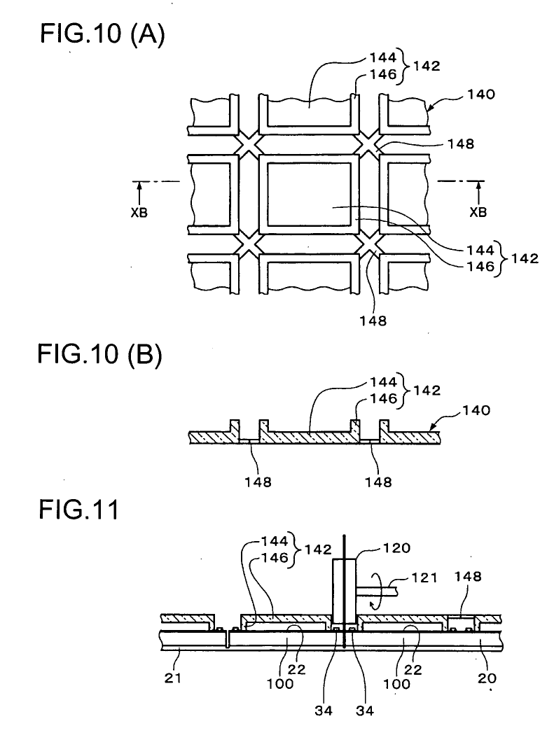

FIG. 10(A) through FIG. 11 are diagrams illustrating a method of manufacturing a semiconductor device according to a third embodiment of the present invention. In the present embodiment, as an example, a method of manufacturing an optical device will be described, too. FIG. 10(B) is a sectional view along the XB-XB line in FIG. 10(A). In the present embodiment, a first substrate 140 is an aggregation of a plurality of covers 142.

The covers 142 include a plate part 144 and a spacer part 146. Although the form of the plate part 144 is not specifically limited, it is, for example, a quadrangle as shown in FIG. 10(A). The plate part 144 is disposed above the optical unit 22. The spacer part 146 is formed into a convex shape on a periphery part of the plate part 144. The spacer part 146 is continuously formed without a break. The spacer part 146 is disposed on a position surrounding the optical unit 22 and supports the plate part 144 above the optical unit 22. The height of the spacer part 146 may be to the extent that a space is formed between the optical unit 22 and the plate part 144. The covers 142 shown in FIG. 10(B) are a member into which the plate part 144 and the spacer part 146 are integrally formed. For example, the cover 142 can be formed by injection molding of resin. Two of the covers 142 adjacent to each other are coupled through a connecting part 148 so that each position is fixed. A plurality of the covers 142 and the connecting part 148 here including a plurality of connecting parts may be integrally formed (by, for example, injection molding).

As shown in FIG. 10(A), a plurality of the covers 142 which are rectangular may be arranged in a matrix. Then, corner parts of two of the covers 142 adjacent to each other may be coupled through the connecting part 148. A plurality of the covers 142 (four, in the example shown in FIG. 10(A)) are connected to each other through a single connecting part 148. The connecting part 148 may be formed thinner than the plate part 144. As shown in FIG. 10 (B), a plane of the connecting part 148 may be flush (or almost flush) with a plane which is on opposite sides to a projecting direction of the spacer part 146, of the plate part 144.

As shown in FIG. 11, the method of manufacturing a semiconductor device according to the present embodiment includes that the connecting part 148 is cut. Namely, a plurality of the covers 142 are attached to the second substrate 20 so as to seal any of the optical units 22 by the covers 142, thereafter the first and the second substrates 140 and 20 are cut in a lump (simultaneously). This cutting is performed using the cutting tool 120. In the example shown in FIG. 11, the substrates are cut so that the connecting part 148 of the first substrate 140 is removed so as to isolate each of the covers 142 into individual pieces. Here, details of the cutting process are the same as the details explained in the first embodiment.

The present embodiment can also achieve the effects which have been previously explained in other embodiments. Other details are the same as the details explained in the first embodiment.

(Other Embodiments)

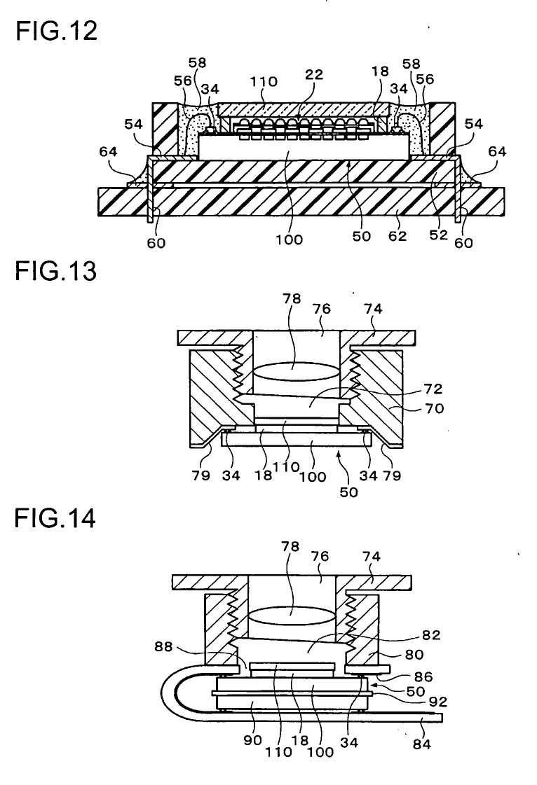

FIG. 12 is a diagram illustrating a semiconductor device (for example, an optical module) and a circuit substrate according to an embodiment of the present invention. This optical module includes an optical device 50 equivalent to the optical device shown in FIG. 6(A). The optical device 50 is attached to a supporting member (for example, a case) 52. A wiring 54 is formed on the supporting member 52. The supporting member 52 may be a member which does not include the wiring 54 and the like. The supporting member 52 may be a molded interconnect device (MID). The wiring 54 is electrically connected to the electrodes 34 of the optical device 50. For example, a wire 56 may be used for electrically connecting. In addition, a sealing material 58 is provided on the electrically connecting point (for example, the wire 56 and a part where the wire 56 is bonded). Namely, the electrically connecting point is sealed by the sealing material 58. The sealing material 58 may be provided by, for example, potting. In the optical device 50, since the optical unit 22 is sealed by the transparent substrate 110 and the spacer 18, the optical unit 22 is not covered by the sealing material 58. This is because the transparent substrate 110 and the spacer 18 act as a dam to block the sealing material 58.

Apart of the wiring 54 is an external terminal (for example, a lead) 60. The external terminal 60 is electrically connected to a wiring pattern 64 formed on a circuit substrate 62. In the example shown in FIG. 12, a portion defining a hole is formed in the circuit substrate 62, and then the external terminal 60 is inserted into the hole. A land of the wiring pattern 64 is formed around the hole. The external terminal 60 is bonded to the land with a brazing material (for example, solder). As described, the circuit substrate 62 is formed by mounting the optical module.

FIG. 13 is a diagram illustrating a semiconductor device (for example, an optical module) according to an embodiment of the present invention. This optical module includes the optical device 50 equivalent to the optical device shown in FIG. 6(A) and a supporting member 70 to which the optical device 50 is attached. A portion defining a hole 72 is formed in the supporting member 70. At least a part of the transparent substrate 110 is located inside the hole 72. In addition, a lens holder 74 is provided in the hole 72. A portion defining a hole 76 is formed in the lens holder 74. A lens 78 is provided inside the hole 76. The holes 72 and 76 communicate with each other, so that light condensed by the lens 78 enters the optical device 50. Here, the transparent substrate 110 may be a member which cuts light in the infrared range. Any adhesive, anisotropic conductive material, anisotropic conductive film, and metal bonding may be applied to connecting the electrodes 34 of the optical device 50 to the wiring 79 of the supporting member 70. Furthermore, an underfill material not shown in the drawing may be provided between the optical device 50 and the supporting member 70.

FIG. 14 is a diagram illustrating a semiconductor device (for example, an optical module) according to an embodiment of the present invention. This optical module includes the optical device 50 equivalent to the optical device shown in FIG. 6(A) and a supporting member 80 to which the optical device 50 is attached. A portion defining a hole 82 is formed in the supporting member 80. At least a part of the transparent substrate 110 is located inside the hole 82. In addition, the lens holder 74 is provided in the hole 82 (as described in detail above).

In FIG. 14, the optical device 50 is mounted onto a substrate 84. The electrodes 34 are bonded to a wiring pattern 86 formed on the substrate 84. Any adhesive, anisotropic conductive material, anisotropic conductive film, and metal bonding may be applied to the bonding. Furthermore, an underfill material not shown in the drawing may be provided between the optical device 50 and the substrate 84. A portion defining a hole 88 is formed in the substrate 84. The holes 76, 82 and 88 communicate with each other, so that light condensed by the lens 78 enters the optical device 50.

An electronic unit (for example, a semiconductor chip) 90 is mounted (by, for example, face-down bonding) onto the substrate 84. The electronic unit 90 and the wiring pattern 86 are electrically connected to each other. Besides, a plurality of electronic units not shown in the drawing may be mounted. The substrate 84 is bent so as to bond the electronic unit 90 to the optical device 50 through an adhesive 92. Alternatively, the optical device 50 and the electronic unit 90 may be mounted onto the substrate 84 beforehand, and then the optical device 50 may be bonded to the electronic unit 90 by bending the substrate 84.

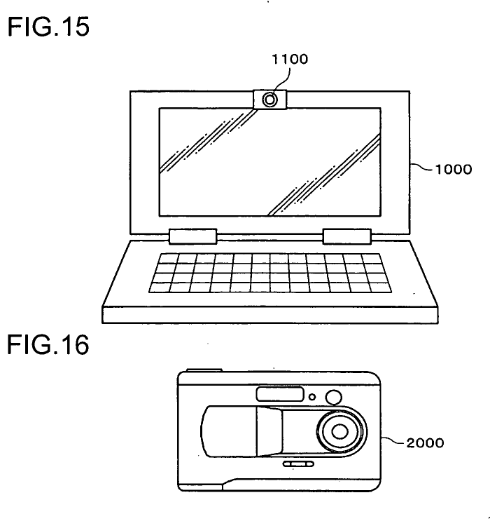

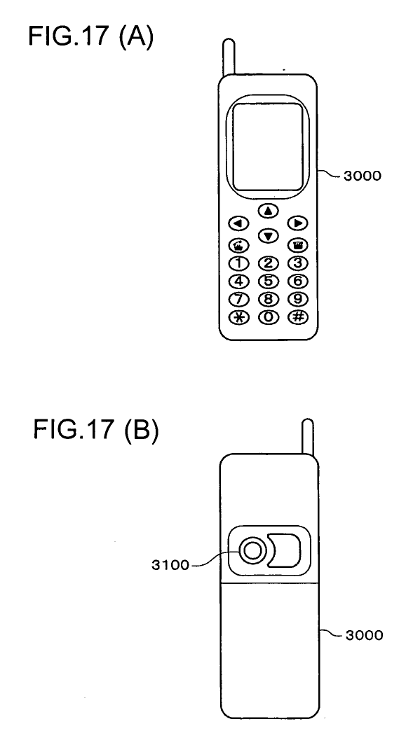

As electronic equipment according to an embodiment of the present invention, a notebook personal computer 1000 shown in FIG. 15 includes a camera 1100 provided with the optical module. In addition, a digital camera 2000 shown in FIG. 16 includes the optical module. Furthermore, a cellular phone 3000 shown in FIG. 17(A) and FIG. 17(B) includes a camera 3100 provided with the optical module.

The present invention is not limited to the above embodiments but applied to various kinds of modifications. For example, the present invention includes a structure which is practically the same as that explained in the embodiments (for example, a structure whose function, method, and result are the same, or a structure whose aim and result are the same). In addition, the present invention includes a structure which is formed by replacing a nonessential parts of the structure explained in the embodiments. Furthermore, the present invention includes a structure having the same operation and result as those of the structure explained in the embodiments, or a structure which can achieve the same purpose as that thereof. In addition, the present invention includes a structure which is formed by adding a known technology to the structure explained in the description of the embodiments.

What is claimed is:

1. A method of manufacturing a semiconductor device, comprising of:
(a) connecting a first substrate with a second substrate disposed to be stacked on the first substrate; and
(b) cutting the first substrate and the second substrate in the same process with a cutting tool, wherein:
the cutting tool includes a plurality of cutters disposed close to each other, having different cut widths; and
the first substrate and the second substrate are cut with the cutting tool so that the first substrate and the second substrate have different cut widths, in step (b).

2. The method of manufacturing a semiconductor device according to claim 1, further comprising:
providing at least a part of the first substrate with optical transparency; and
forming the second substrate to include a part which becomes an optical chip including an optical unit with the part including at least a plurality of parts.

3. The method of manufacturing a semiconductor device according to claim 1 further comprising inserting the cutting tool into the first substrate and the second substrate from a side of the first substrate.

4. The method of manufacturing a semiconductor device according to claim 3, further comprising:
cutting the first substrate with a first cutter and cutting the second substrate with a second cutter; and
cutting a cut width of the first substrate by the first cutter larger than cutting a cut width of the second substrate by the second cutter, in step (b).

5. The method of manufacturing a semiconductor device according to claim 4, further comprising providing the length of the first cutter larger than the thickness of a part which is cut, of the first substrate.

6. The method of manufacturing a semiconductor device according to claim 4, further comprising providing the length of the second cutter is larger than the thickness of a part which is cut, of the second substrate.

7. The method of manufacturing a semiconductor device according to claim 4 further comprising positioning the first cutter with an interval from a surface of the second substrate at the time of cutting the second substrate.

8. The method of manufacturing a semiconductor device according to claim 4, further comprising:
forming an electrode on the part which becomes an optical chip on the second substrate, and outside the optical unit; and
removing a part of the first substrate located above the electrode with the first cutter in step (b).

9. The method of manufacturing a semiconductor device according to claim 8, further comprising:
attaching a sheet to the second substrate before step (b); and
cutting the second substrate not so as to penetrate the sheet with the cutting tool in step (b).

10. The method of manufacturing a semiconductor device according to claim 1, further comprising:
forming a trench along a cut line of the first substrate before step (b); and
cutting the first substrate along the cut line in step (b).

11. The method of manufacturing a semiconductor device according to claim 1, further comprising cutting and separating the first substrate and the second substrate into individual pieces that include a part of the first substrate and a part of the second substrate which are placed face to face and fixed to each other.

12. The method of manufacturing a semiconductor device according to claim 1, further comprising:
placing the first substrate and the second substrate face to face through a spacer; and
fixing the first substrate to the second substrate through the spacer.

13. The method of manufacturing a semiconductor device according to claim 1, further comprising:
bonding the first substrate with the second substrate through an optically transparent adhesive; and
fixing the first substrate to the second substrate through the optically transparent adhesive.

14. The method of manufacturing a semiconductor device according to claim 1, further comprising:
forming a connecting part which connects a plurality of covers to each other in the first substrate;
fixing a plurality of the covers to the second substrate in step (a); and
cutting the connecting part in step (b).

15. A semiconductor device manufactured by the method of manufacturing a semiconductor device according to claim 1.

16. A semiconductor device comprising the semiconductor device according to claim 15 and a supporting member which supports the semiconductor device.

17. A circuit substrate comprising the semiconductor device according to claim 15.

18. Electronic equipment comprising the semiconductor device according to claim 15.

19. A semiconductor device, comprising:
a first substrate with a second substrate disposed to be stacked on the first substrate; and
a cutting tool cutting the first substrate and the second substrate in the same process, wherein:
the cutting tool includes a plurality of cutters disposed close to each other, having different cut widths, and
the first substrate and the second substrate are cut with the cutting tool so that the first substrate and the second substrate have different cut widths.

20. A semiconductor device, comprising:
a first substrate connected with a second substrate disposed to be stacked on the first substrate; and
means for cutting the first substrate and the second substrate in the same process, wherein:
the means for cutting includes a plurality of cutters disposed close to each other, having different cut widths, and
the first substrate and the second substrate are cut with the means for cutting so that the first substrate and the second substrate have different cut widths.
